(19) United States
(12) Patent Application Publication
(10) Pub. No.: US 2025/0248229 A1
(43) Pub. Date: Jul. 31, 2025

(54) DISPLAY DEVICE

(71) Applicant: Japan Display Inc., Tokyo (JP)

(72) Inventor: Hirofumi FUNAKOSHI, Tokyo (JP)

(73) Assignee: Japan Display Inc., Tokyo (JP)

(21) Appl. No.: 19/022,404

(22) Filed: Jan. 15, 2025

(30) Foreign Application Priority Data
Jan. 30, 2024 (JP) 2024-011695

(51) Int. Cl. H10K 59/122; H10K 59/12; H10K 59/35; H10K 59/80

(52) U.S. Cl. CPC H10K 59/122; H10K 59/873; H10K 59/1201; H10K 59/352

(57) ABSTRACT

According to one embodiment, a display device includes a first pixel provided in a display area which displays an image, a transmissive area provided in the display area, and a partition which includes a conductive lower portion and an upper portion having an end portion protruding from a side surface of the lower portion, and is provided in the display area. The first pixel includes a plurality of subpixels surrounded by the partition. The transmissive area includes a plurality of sub-areas which are surrounded by the partition and transmit at least part of light which enters the transmissive area.

### CROSS-REFERENCE TO RELATED APPLICATIONS

This application is based upon and claims the benefit of priority from Japanese Patent Application No. 2024-011695, filed Jan. 30, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area.

In some cases, translucency is required in at least part of the display area in which the display elements are arrayed. However, if the above lower electrodes and lines are formed of a material having light-shielding properties, such as metal, the translucency of the display device could be considerably decreased.

### BRIEF DESCRIPTION OF THE DRAWINGS

FIG. 1 is a diagram showing a configuration example of a display device according to a first embodiment.

FIG. 2 is a circuit diagram showing an example of a configuration which can be applied to the pixel circuit provided in each subpixel.

FIG. 3 is a schematic plan view showing an example of the layout of the subpixels in one pixel.

FIG. 4 is the schematic cross-sectional view of a display panel along the IV-IV line of FIG. 3.

FIG. 5 is a schematic plan view showing part of a first area.

FIG. 6 is a schematic plan view showing part of a second area.

FIG. 7 is another schematic plan view showing part of the second area.

FIG. 8 is the schematic cross-sectional view of the second area along the VIII-VIII line of FIG. 6.

FIG. 9 is a schematic cross-sectional view showing another configuration which can be applied to the second area.

FIG. 10 is a schematic plan view showing yet another configuration which can be applied to the second area.

FIG. 11 is a schematic plan view showing another example of the apertures of a rib layer.

FIG. 12 is the schematic cross-sectional view of the second area along the XII-XII line of FIG. 10.

FIG. 13A is a schematic cross-sectional view showing the manufacturing process of the display device.

FIG. 13B is a schematic cross-sectional view showing a process following FIG. 13A.

FIG. 13C is a schematic cross-sectional view showing a process following FIG. 13B.

FIG. 13D is a schematic cross-sectional view showing a process following FIG. 13C.

FIG. 13E is a schematic cross-sectional view showing a process following FIG. 13D.

FIG. 13F is a schematic cross-sectional view showing a process following FIG. 13E.

FIG. 13G is a schematic cross-sectional view showing a process following FIG. 13F.

FIG. 13H is a schematic cross-sectional view showing a process following FIG. 13G.

FIG. 13I is a schematic cross-sectional view showing a process following FIG. 13H.

FIG. 14 is a schematic plan view showing part of a second area according to a second embodiment.

FIG. 15 is a schematic plan view showing part of a second area according to a third embodiment.

### DETAILED DESCRIPTION

In general, according to one embodiment, a display device comprises a first pixel provided in a display area which displays an image, a transmissive area provided in the display area, and a partition which includes a conductive lower portion and an upper portion having an end portion protruding from a side surface of the lower portion, and is provided in the display area. The first pixel includes a plurality of subpixels surrounded by the partition. The transmissive area includes a plurality of sub-areas which are surrounded by the partition and transmit at least part of light which enters the transmissive area.

The embodiment can provide a display device with excellent translucency.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

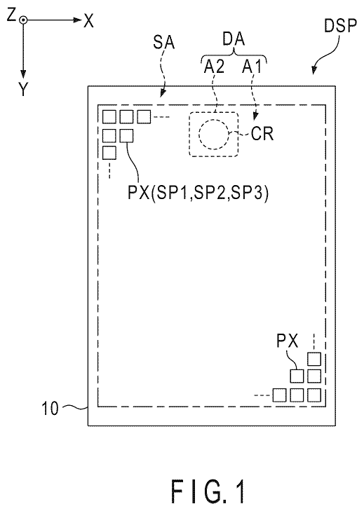

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In this embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel includes a plurality of subpixels SP which display different colors. The embodiment assumes a case where each pixel PX includes three subpixels (first to third subpixels) SP1, SP2 and SP3. For example, subpixel SP1 displays green, and subpixel SP2 displays blue, and subpixel SP3 displays red. It should be noted that the colors displayed by subpixels SP1, SP2 and SP3 are not limited to this example. Each pixel PX may include a subpixel SP which exhibits another color such as white in addition to subpixels SP1, SP2 and SP3 or instead of one of subpixels SP1, SP2 and SP3.

The display area DA includes a first area A1 and a second area A2 having a translucency which is higher than the first area A1. For example, a camera CR is provided on the back surface side of the second area A2. This camera CR can capture the target object located on the display surface side through the second area A2. In place of the camera CR, another type of photoreceiver such as an illumination sensor which detects external light may be provided. The display area DA may include a plurality of second areas A2 facing the camera CR and the illumination sensor.

For example, the second area A2 is smaller than the first area A1. In the example of FIG. 1, the second area A2 is located near an end portion of the display area DA and is surrounded by the first area A1. However, the layout position of the second area A2 is not limited to this example. The second area A2 may not be necessarily surrounded by the first area A1 in the whole circumference and may be provided such that one side or two sides face the surrounding area SA. The second area A2 is, for example, rectangular. However, the second area A2 may have another shape such as a circular shape.

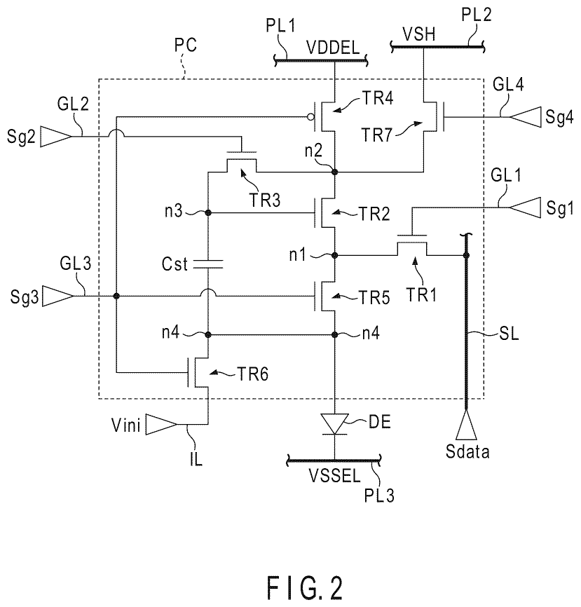

FIG. 2 is a circuit diagram showing an example of a configuration which can be applied to the pixel circuit PC provided in each subpixel SP (SP1, SP2 or SP3). The pixel circuit PC shown in this figure includes seven transistors TR1 to TR7 and one storage capacitor Cst.

In the following explanation, one of the source and drain electrodes of each of the transistors TR1 to TR7 is referred to as a first electrode, and the other one is referred to as a second electrode. Similarly, one of a pair of electrodes constituting the storage capacitor Cst is referred to as a first electrode, and the other one is referred to as a second electrode.

The first electrode of the transistor TR1 is connected to a node n1. The second electrode of the transistor TR1 is connected to a signal line SL which supplies video signals Sdata. Video signals Sdata are signals which are written to pixels for image display.

The transistor TR2 corresponds to a drive transistor which supplies current to a light emitting element DE included in the subpixel SP. The first electrode of the transistor TR2 is connected to the node n1. The second electrode of the transistor TR2 is connected to a node n2.

The first electrode of the transistor TR3 is connected to a node n3. The second electrode of the transistor TR3 is connected to the node n2.

The first electrode of the transistor TR4 is connected to the node n2. The second electrode of the transistor TR4 is connected to a power line PL1 which applies power source voltage VDDEL.

The first electrode of the transistor TR5 is connected to a node n4. The second electrode of the transistor TR5 is connected to the node n1.

The first electrode of the transistor TR6 is connected to the node n4. The second electrode of the transistor TR6 is connected to an initialization line IL which applies initialization voltage Vini.

The first electrode of the transistor TR7 is connected to the node n2. The second electrode of the transistor TR7 is connected to a power line PL2 which applies power source voltage VSH.

The first electrode of the storage capacitor Cst is connected to the node n3. The second electrode of the storage capacitor Cst is connected to the node n4.

The gate electrode of the transistor TR1 is connected to a scanning line GL1 which supplies scanning signals Sg1. The gate electrode of the transistor TR3 is connected to a scanning line GL2 which supplies scanning signals Sg2. The gate electrodes of the transistors TR4, TR5 and TR6 are connected to a scanning line GL3 which supplies scanning signals Sg3. The gate electrode of the transistor TR7 is connected to a scanning line GL4 which supplies scanning signals Sg4.

The anode of the display element DE is connected to the node n4. The cathode of the display element DE is connected to a power line PL3 which applies power source voltage VSSEL. Power source voltage VDDEL corresponds to anode voltage which is applied to the display element DE. Power source voltage VSSEL corresponds to cathode voltage which is applied to the display element DE.

It should be noted that the configuration of the pixel circuit PC is not limited to the example shown in FIG. 2. For example, the pixel circuit PC may comprise six or less or eight or more transistors. Further, the pixel circuit PC may comprise a plurality of storage capacitors Cst. The number of scanning lines and power lines connected to the pixel circuit PC may be increased or decreased depending on the configuration of the pixel circuit PC.

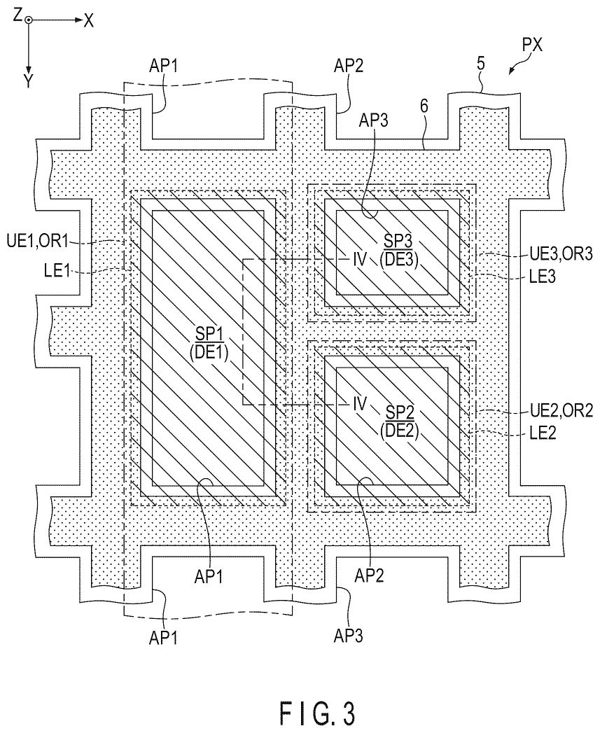

FIG. 3 is a schematic plan view showing an example of the layout of subpixels SP1, SP2 and SP3 in one pixel PX. In the example of FIG. 3, each of subpixels SP2 and SP3 is adjacent to subpixel SP1 in the X-direction. Further, subpixels SP2 and SP3 are arranged in the Y-direction. It should be noted that the layout of subpixels SP1, SP2 and SP3 is not limited to the example of FIG. 3.

A rib layer 5 is provided in the display area DA. The rib layer 5 has pixel apertures AP1, AP2 and AP3 in subpixels SP1, SP2 and SP3, respectively. In the example of FIG. 3, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3. In FIG. 3, a diagonal pattern is added to the lower electrodes LE1, LE2 and LE3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib layer 5 surrounds each of these display elements DE1, DE2 and DE3.

A conductive partition 6 is provided on the rib layer 5. In FIG. 3, a dot pattern is added to the partition 6. The partition 6 overlaps the rib layer 5 as a whole and has a planar shape similar to that of the rib layer 5. In other words, the partition 6 has an aperture in each of subpixels SP1, SP2 and SP3. From another viewpoint, each of the rib layer 5 and the partition 6 has a grating shape as seen in plan view, and surrounds each of subpixels SP1, SP2 and SP3 (the display elements DE1, DE2 and DE3). The partition 6 functions as lines which apply common voltage to the upper electrodes UE1, UE2 and UE3.

In the example of FIG. 3, the end portions of the lower electrodes LE1, LE2 and LE3 overlap the rib layer 5 and the partition 6 as a whole. As another example, at least part of the end portions of the lower electrodes LE1, LE2 and LE3 may not overlap the partition 6.

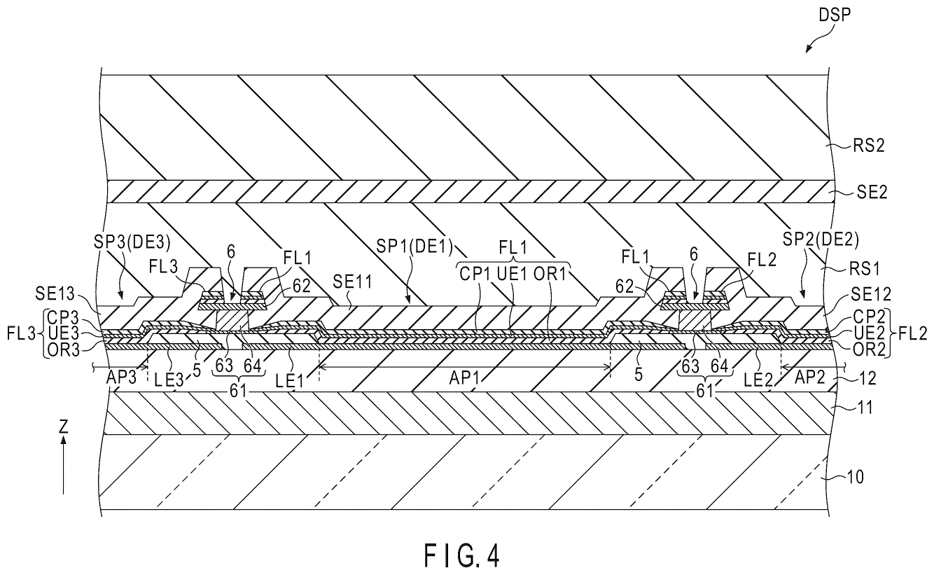

FIG. 4 is the schematic cross-sectional view of a display panel PNL along the IV-IV line of FIG. 3. A circuit layer 11 is provided on the substrate 10 described above. The circuit layer 11 includes various circuits and lines such as the pixel circuit PC, scanning lines GL1 to GL4, signal line SL, power lines PL1 to PL3 and initialization line IL shown in FIG. 2. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 4, the lower electrodes LE1, LE2 and LE3 are connected to the respective pixel circuits PC of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 4, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 4, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located around the partition 6 (in other words, the portion which constitutes the display element DE1). Similarly, the stacked film FL2 is partly located on the upper portion 62. This portion is spaced apart from, of the stacked film FL2, the portion located around the partition 6 (in other words, the portion which constitutes the display element DE2). Further, the stacked film FL3 is partly located on the upper portion 62. This portion is spaced apart from, of the stacked film FL3, the portion located around the partition 6 (in other words, the portion which constitutes the display element DE3).

Sealing layers (first sealing layers) SE11, SE12 and SE13 are provided in subpixels SP1, SP2 and SP3, respectively. The sealing layer SE11 continuously covers the cap layer CP1 and the partition 6 around subpixel SP1. The sealing layer SE12 continuously covers the cap layer CP2 and the partition 6 around subpixel SP2. The sealing layer SE13 continuously covers the cap layer CP3 and the partition 6 around subpixel SP3.

In the example of FIG. 4, the stacked film FL1 and sealing layer SE11 located on the partition 6 between subpixels SP1 and SP2 are spaced apart from the stacked film FL2 and sealing layer SE12 located on this partition 6. The stacked film FL1 and sealing layer SE11 located on the partition 6 between subpixels SP1 and SP3 are spaced apart from the stacked film FL3 and sealing layer SE13 located on this partition 6.

The sealing layers SE11, SE12 and SE13 are covered with a resin layer (first resin layer) RS1. The resin layer RS1 is covered with a sealing layer (second sealing layer) SE2. The sealing layer SE2 is covered with a resin layer (second resin layer) RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 comprises a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may comprise another structure such as a tandem structure including a plurality of light emitting layers.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) can be used. For the metal material of the stem layer 64, for example, aluminum, an aluminum-neodymium alloy (AlNd), an aluminum-yttrium alloy (AlY) or an aluminum-silicon alloy (AlSi) can be used. It should be noted that the stem layer 64 may be formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits PC provided in subpixels SP1, SP2 and SP3, respectively, based on the video signals of the signal lines SL.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a green wavelength range. When a potential difference is formed between the lower electrode LE2 and the upper electrode UE2, the light emitting layer of the organic layer OR2 emits light in a blue wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

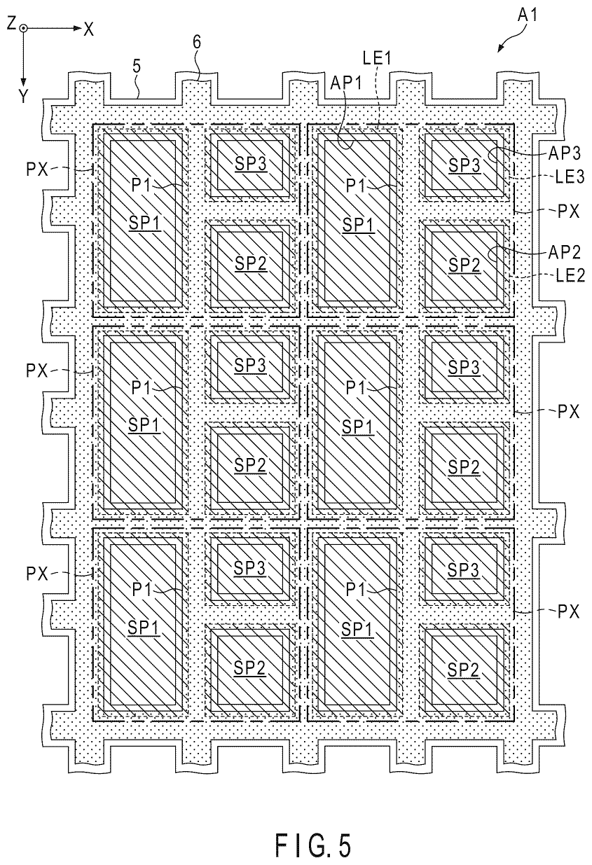

FIG. 5 is a schematic plan view showing part of the first area A1. In this figure, the rib layer 5, the partition 6 and the lower electrodes LE1, LE2 and LE3 are shown, and the other elements are omitted. A dot pattern is added to the partition 6. A diagonal pattern is added to the lower electrodes LE1, LE2 and LE3.

In the first area A1, a plurality of pixels PX are arranged in the X-direction and the Y-direction. The layout of subpixels SP1, SP2 and SP3 in each pixel PX is the same as the example of FIG. 2. Thus, a column in which a plurality of subpixels SP1 are repeatedly provided in the Y-direction and a column in which subpixels SP2 and SP3 are alternately provided in the Y-direction are formed in the first area A1. These columns are alternately arranged in the X-direction.

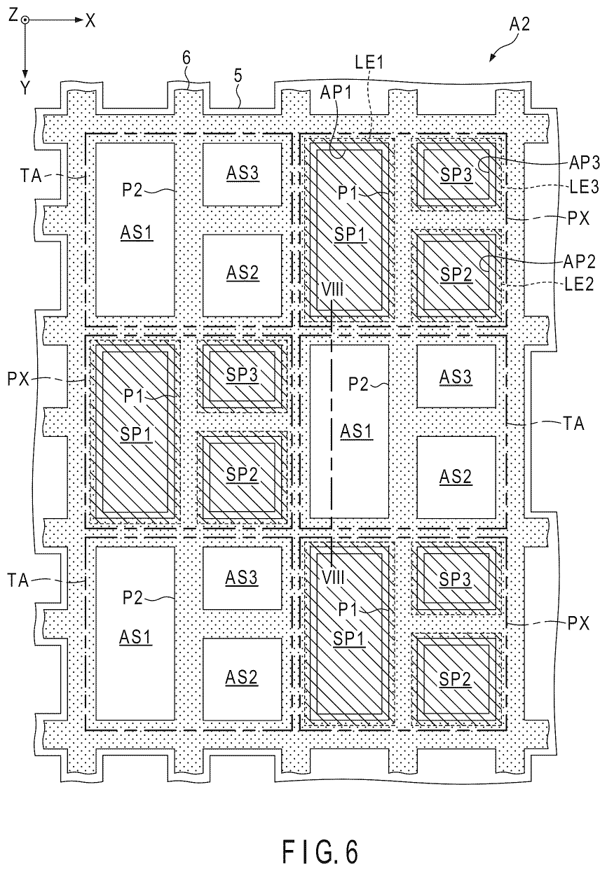

FIG. 6 is a schematic plan view showing part of the second area A2. In FIG. 6, in a manner similar to that of FIG. 5, the rib layer 5, the partition 6 and the lower electrodes LE1, LE2 and LE3 are shown, and the other elements are omitted. A dot pattern is added to the partition 6. A diagonal pattern is added to the lower electrodes LE1, LE2 and LE3.

The second area A2 has a plurality of pixels PX and a plurality of transmissive areas TA. The layout of subpixels SP1, SP2 and SP3 in each pixel PX of the second area A2 is the same as each pixel PX of the first area A1.

Each transmissive area TA has a size which is equal to that of each pixel PX. In the example of FIG. 6, each pixel PX and each transmissive area TA are alternately arranged in the X-direction and the Y-direction. In other words, in the second area A2, pixels PX are provided at a density which is half of the first area A1. The configuration is not limited to this example. For example, a plurality of transmissive areas TA may be provided between two pixels PX which are adjacent to each other in the X-direction or Y-direction. A plurality of pixels PX may be provided between two transmissive areas TA which are adjacent to each other in the X-direction or Y-direction.

Each transmissive area TA includes a plurality of sub-areas AS each of which is surrounded by the partition 6. For example, each sub-area AS transmits at least part of the light which enters the transmissive area TA from the display surface side of the display device DSP toward the back surface side of the display device DSP. By this configuration, as explained above with reference to FIG. 1, the translucency of the second area A2 is increased compared to the first area A1.

In the example of FIG. 6, three sub-areas (first to third sub-areas) AS1, AS2 and AS3 are formed in each transmissive area TA. In other words, the number of subpixels SP (SP1, SP2 and SP3) in each pixel PX and the number of sub-areas AS (AS1, AS2 and AS3) in each transmissive area TA are three, and thus, the same as each other. However, the number of subpixels SP in each pixel PX may not be necessarily the same as the number of sub-areas AS in each transmissive area TA.

In the example of FIG. 6, the shape of each subpixel SP1 is the same as that of each sub-area AS1. The shape of each subpixel SP2 is the same as that of each sub-area AS2. The shape of each subpixel SP3 is the same as that of each sub-area AS3. Here, the shapes of subpixels and sub-areas indicate the shapes of the areas surrounded by the partition 6 in plan view.

In the example of FIG. 6, the sub-areas AS2 and AS3 are arranged in the Y-direction. Further, each of the sub-areas AS2 and AS3 is adjacent to the sub-area AS1 in the X-direction. In other words, the positional relationship of the sub-areas AS1, AS2 and AS3 is the same as that of subpixels SP1, SP2 and SP3.

The partition 6 has a first part P1 which defines subpixels SP1, SP2 and SP3 in each pixel PX, and a second part P2 which defines the sub-areas AS1, AS2 and AS3 in each transmissive area TA. In the example of FIG. 6, the shapes of these first part P1 and second part P2 are the same as each other. Specifically, the first part P1 has a portion extending in the Y-direction between subpixel SP1 and subpixels SP2 and SP3, and a portion extending in the X-direction between subpixel SP2 and subpixel SP3. The second part P2 has a portion extending in the Y-direction between the sub-area AS1 and the sub-areas AS2 and AS3, and a portion extending in the X-direction between the sub-area AS2 and the sub-area AS3.

As described above, the lower electrodes LE1, LE2 and LE3 are provided in subpixels SP1, SP2 and SP3. Further, the pixel apertures AP1, AP2 and AP3 which overlap these lower electrodes LE1, LE2 and LE3, respectively, are provided in the rib layer 5.

To the contrary, the lower electrode LE1, LE2 or LE3 is not provided in the sub-area AS1, AS2 or AS3. Further, in the example of FIG. 6, the rib layer 5 does not have an aperture in the sub-area AS1, AS2 or AS3. In other words, the sub-areas AS1, AS2 and AS3 overlap the rib layer 5 as a whole.

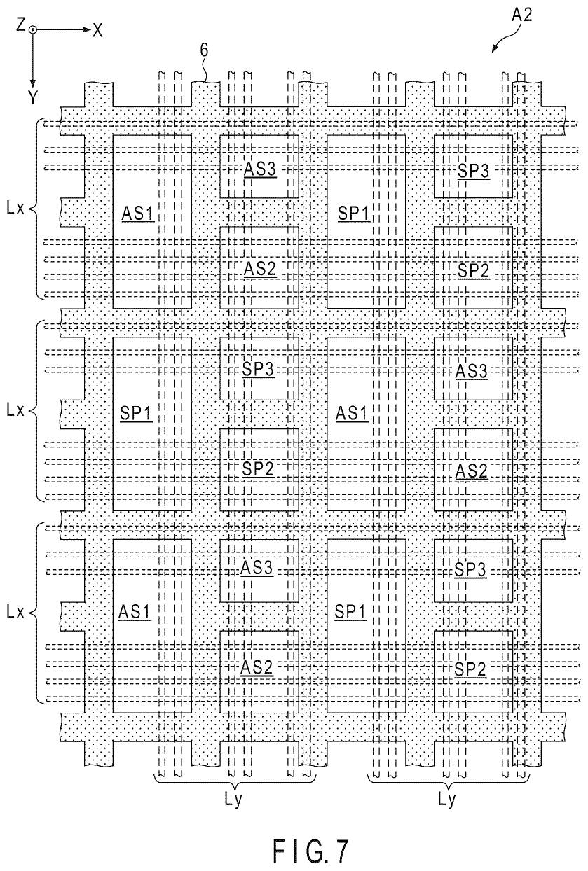

FIG. 7 is another schematic plan view showing part of the second area A2. Various lines for driving subpixels SP1, SP2 and SP3 are provided in the second area A2. These lines include a plurality of lines Lx extending in the X-direction and a plurality of lines Ly extending in the Y-direction. All of the lines Lx and Ly are formed by a metal layer included in the circuit layer 11 shown in FIG. 4.

For example, the lines Lx include the scanning lines GL1 to GL4, power lines PL2 and PL3 and initialization line IL shown in FIG. 2. The lines Ly include the signal line SL and power line PL1 shown in FIG. 2.

In the example of FIG. 7, a large part of the lines Lx crosses subpixels SP1, SP2 and SP3 and the sub-areas AS1, AS2 and AS3 in the X-direction. In addition, a large part of the lines Ly crosses subpixels SP1, SP2 and SP3 and the sub-areas AS1, AS2 and AS3 in the Y-direction.

The lines Lx and Ly formed by the metal layer have light-shielding properties. In the sub-areas AS1, AS2 and AS3, light passes through the portions which do not overlap the lines Lx or Ly. To the contrary, in subpixels SP1, SP2 and SP3, a large part of light which enters the display device DSP is reflected on or absorbed by the lower electrodes LE1, LE2 and LE3.

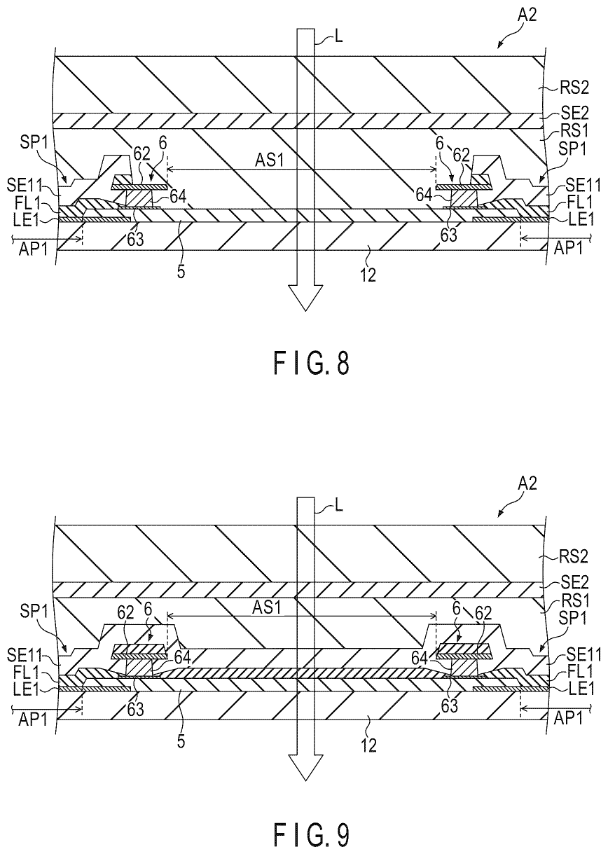

FIG. 8 is the schematic cross-sectional view of the second area A2 along the VIII-VIII line of FIG. 6. In this figure, the substrate 10 and the circuit layer 11 are omitted.

As described above, the rib layer 5 does not have an aperture in the sub-area AS1, AS2 or AS3. Further, in the sub-area AS1, AS2 or AS3, the lower electrode LE1, LE2 or LE3 is not provided.

In addition, in the example of FIG. 8, none of the stacked films FL1, FL2 and FL3 (the organic layers OR1, OR2 and OR3, the upper electrodes UE1, UE2 and UE3 and the cap layers CP1, CP2 and CP3) and the sealing layers SE11, SE12 and SE13 is provided in the sub-area AS1. By this configuration, the rib layer 5 is in contact with the resin layer RS1 in the sub-area AS1. In the sub-area AS2 or AS3, similarly, none of the stacked films FL1, FL2 and FL3 and the sealing layers SE11, SE12 and SE13 is provided, and the rib layer 5 is in contact with the resin layer RS1.

In this configuration, at least part of light L which enters the second area A2 from the display surface side passes through the sub-areas AS1, AS2 and AS3. Thus, light L can be detected by a photoreceiver such as the camera CR shown in FIG. 1.

FIG. 9 is a schematic cross-sectional view showing another example which can be applied to the second area A2. In the example of this figure, the stacked film FL1 and the sealing layer SE11 are provided in the sub-area AS1. The stacked film FL1 is divided by the partition 6 around the sub-area AS1. The sealing layer SE11 continuously covers the divided stacked film FL1 and the partition 6.

Even in this configuration, at least part of light L which enters the second area A2 passes through the sub-area AS1. However, since light L passes through the stacked film FL1 and the sealing layer SE11, the transmittance may be decreased compared to the example of FIG. 8. In this regard, the configuration shown in FIG. 8 is advantageous.

A configuration which is similar to that of FIG. 9 can be also applied to the sub-areas AS2 and AS3. Specifically, the stacked film FL2 and the sealing layer SE12 may be provided in the sub-area AS2, and the stacked film FL3 and the sealing layer SE13 may be provided in the sub-area AS3.

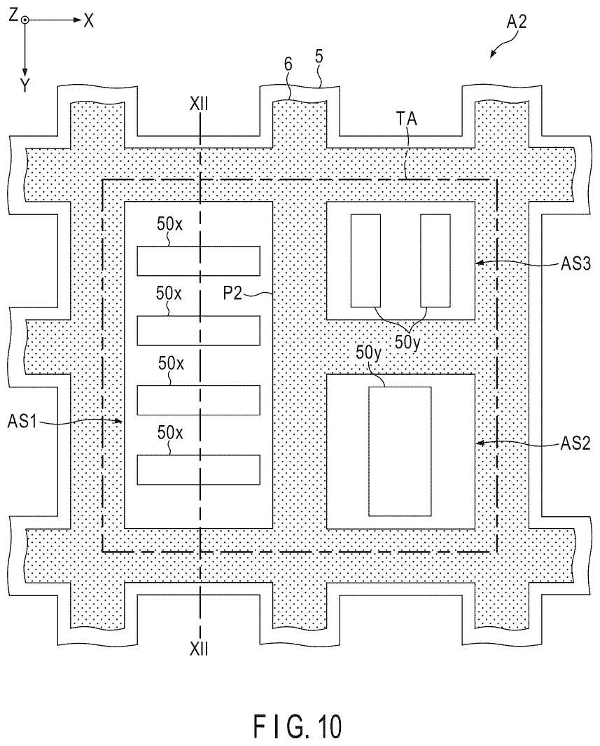

FIG. 10 is a schematic plan view showing yet another configuration which can be applied to the second area A2. In this figure, the rib layer 5 and partition 6 located around the transmissive area TA are shown, and the other elements are omitted.

The rib layer 5 may have an aperture 50 which overlaps at least one of the sub-areas AS1, AS2 and AS3. In the example of FIG. 10, as examples of the aperture 50, a plurality of linear apertures 50x extending in the X-direction and a plurality of linear apertures 50y extending in the Y-direction are shown.

Specifically, four linear apertures 50x arranged in the Y-direction are provided in the sub-area AS1. One linear aperture 50y is provided in the sub-area AS2. Two linear apertures 50y arranged in the X-direction are provided in the sub-area AS3. The width of the linear aperture 50y of the sub-area AS2 in the X-direction is greater than that of each linear aperture 50y of the sub-area AS3 in the X-direction.

The number of linear apertures 50x or 50y provided in the sub-area AS1, AS2 or AS3, their shapes or the layout format is not limited to the example of FIG. 10. For example, the linear aperture 50x may be provided in each of the sub-areas AS1, AS2 and AS3. Further, the linear-aperture 50y may be provided in each of the sub-areas AS1, AS2 and AS3.

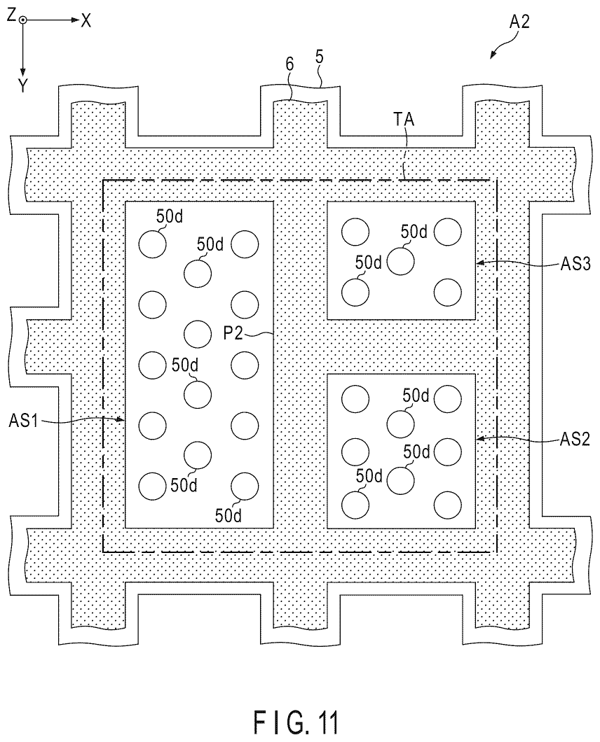

FIG. 11 is a schematic plan view showing another example of the aperture 50. In the example of this figure, a plurality of dot apertures 50d are dispersed in each of the sub-areas AS1, AS2 and AS3.

In the example of FIG. 11, the dot apertures 50d are precise circles having the same diameter. The shape is not limited to this example. Each dot aperture 50d may have another shape such as an oval or a square. The diameters (or widths) of the dot apertures 50d may be different from each other. The dot apertures 50d may be provided in the sub-areas AS1, AS2 and AS3 in addition to the linear apertures 50x and 50y shown in FIG. 10.

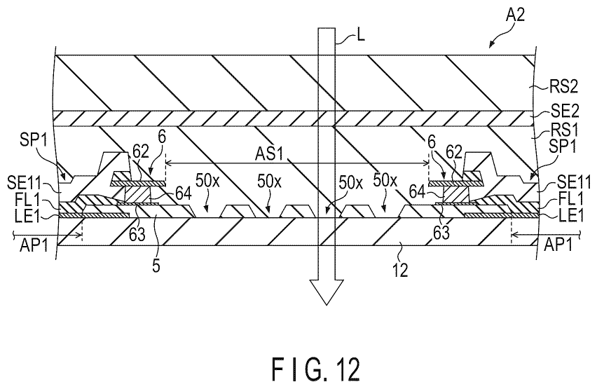

FIG. 12 is the schematic cross-sectional view of the second area A2 along the XII-XII line of FIG. 10. In the example of FIG. 12, in a manner similar to that of FIG. 8, none of the stacked films FL1, FL2 and FL3 and the sealing layers SE11, SE12 and SE13 is provided in the sub-area AS1. Thus, each linear aperture 50x is filled with the resin layer RS1. The resin layer RS1 is in contact with the organic insulating layer 12 through each linear aperture 50x.

As another example, in a manner similar to that of FIG. 9, the stacked film FL1 and the sealing layer SE11 may be provided in the sub-area AS1. In this case, the stacked film FL1 (specifically, the organic layer OR1) is in contact with the organic insulating layer 12 through each linear aperture 50x. In the sub-areas AS2 and AS3, similarly, the stacked films FL2 and FL3 and the sealing layers SE12 and SE13 may be provided, or they may not be provided.

In a case where the apertures 50 such as the linear apertures 50x or 50y or the dot apertures 50d are provided in the rib layer 5 in the sub-areas AS1, AS2 and AS3, the reduction in the transmittance by the rib layer 5 can be prevented. By this configuration, the translucency of each transmissive area TA is further improved.

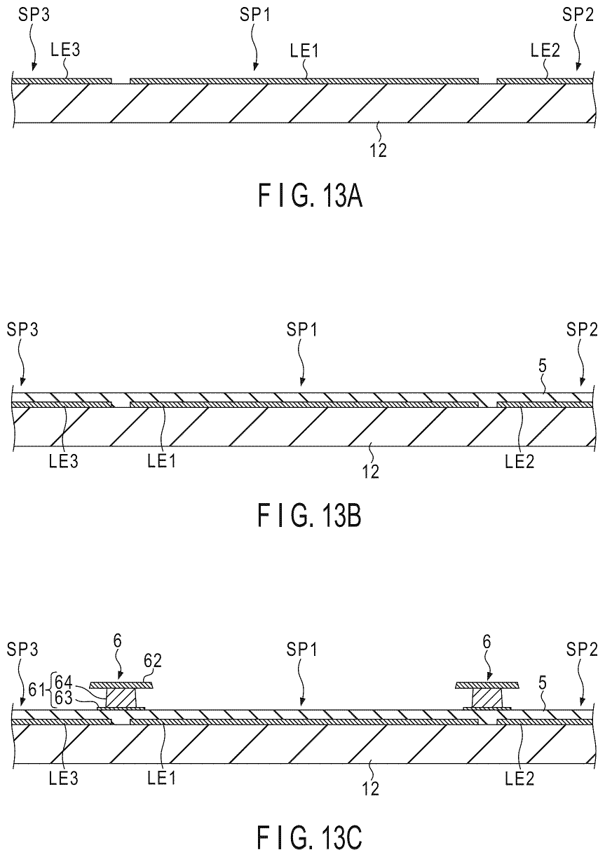

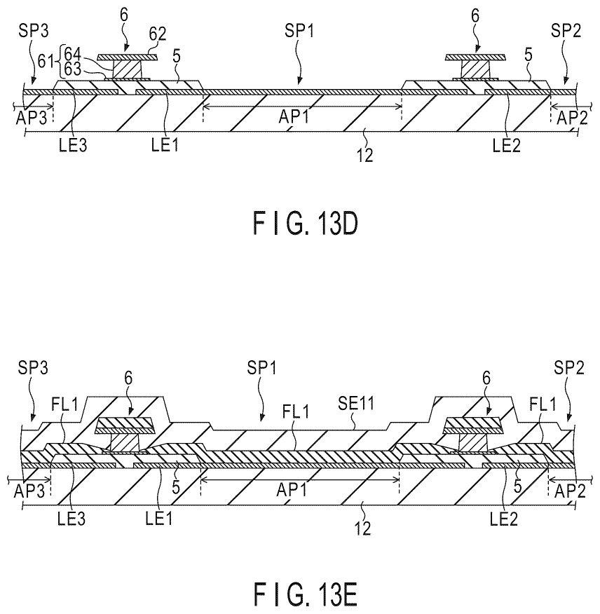

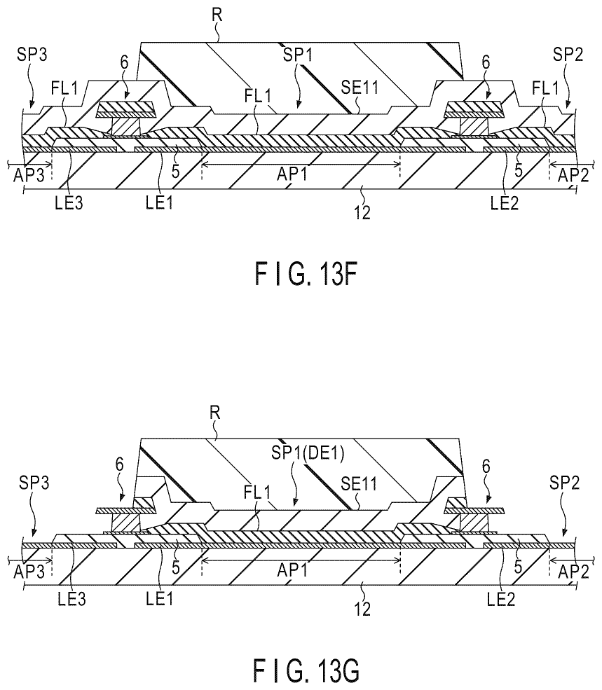

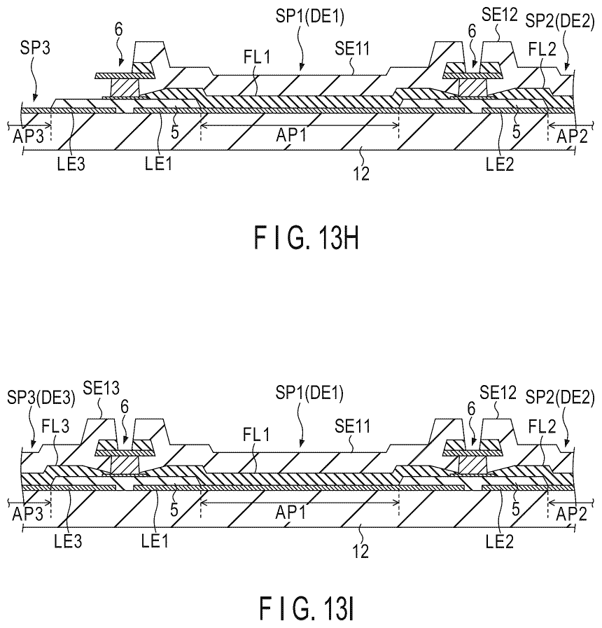

Now, this specification explains an example of the manufacturing method of the display device DSP. Each of FIG. 13A to FIG. 13I is a schematic cross-sectional view showing the manufacturing process of the display device DSP. In FIG. 13A to FIG. 13I, the display area DA is mainly looked at, and the elements located under the organic insulating layer 12 are omitted.

To form the display device DSP, first, the circuit layer 11 and the organic insulating layer 12 are formed on the substrate 10. Subsequently, as shown in FIG. 13A, the lower electrodes LE1, LE2 and LE3 are formed on the organic insulating layer 12.

Subsequently, as shown in FIG. 13B, the rib layer 5 which covers the organic insulating layer 12 and the lower electrodes LE1, LE2 and LE3 is formed. For example, chemical vapor deposition (CVD) can be used for the formation of the rib layer 5.

Further, as shown in FIG. 13C, the partition 6 is formed on the rib layer 5. Specifically, first, the base layers of the bottom layer 63, the stem layer 64 and the upper portion 62 are formed, and these layers are patterned by etching.

After the formation of the partition 6, as shown in FIG. 13D, the pixel apertures AP1, AP2 and AP3 are formed in the rib layer 5 by dry etching.

Subsequently, a process for forming the display elements DE1, DE2 and DE3 is performed. In the present embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 13E, the stacked film FL1 and the sealing layer SE11 are formed. The stacked film FL1 includes, as shown in FIG. 4, the organic layer OR1 which is in contact with the lower electrode LE1 through the pixel aperture AP1, the upper electrode UE1 which covers the organic layer OR1 and the cap layer CP1 which covers the upper electrode UE1. The organic layer OR1, the upper electrode UE1 and the cap layer CP1 are formed by vapor deposition. The sealing layer SE11 is formed by CVD.

The stacked film FL1 and the sealing layer SE11 are formed in the surrounding area SA as well as the display area DA. The stacked film FL1 is divided into a plurality of portions by the partition 6 having an overhang shape. The sealing layer SE11 continuously covers the portions into which the stacked film FL1 is divided, and the partition 6.

Subsequently, the stacked film FL1 and the sealing layer SE11 are patterned. In this patterning, as shown in FIG. 13F, a resist R is provided on the sealing layer SE11. The resist R covers subpixel SP1 and part of the partition 6 around the subpixel.

Subsequently, as shown in FIG. 13G, the portions of the stacked film FL1 and the sealing layer SE11 exposed from the resist R are removed by etching using the resist R as a mask. In other words, of the stacked film FL1 and the sealing layer SE11, the portions which overlap the lower electrode LE1 remain, and the other portions are removed. By this process, the display element DE1 is formed in subpixel SP1. This etching could include wet etching and dry etching processes which are performed in order for the sealing layer SE11, the cap layer CP1, the upper electrode UE1 and the organic layer OR1. After these etching processes, the resist R is removed.

The display element DE2 is formed by a procedure similar to that of the display element DE1. Specifically, when the display element DE2 is formed, the stacked film FL2 and the sealing layer SE12 are formed in the entire display area DA and surrounding area SA. The stacked film FL2 includes, as shown in FIG. 4, the organic layer OR2 which is in contact with the lower electrode LE2 through the pixel aperture AP2, the upper electrode UE2 which covers the organic layer OR2 and the cap layer CP2 which covers the upper electrode UE2.

The organic layer OR2, the upper electrode UE2 and the cap layer CP2 are formed by vapor deposition. The sealing layer SE12 is formed by CVD. The stacked film FL2 is divided into a plurality of portions by the partition 6 having an overhang shape. The sealing layer SE12 continuously covers the portions into which the stacked film FL2 is divided, and the partition 6. By patterning these stacked film FL2 and sealing layer SE2, the display element DE2 is formed in subpixel SP2 as shown in FIG. 13H.

The display element DE3 is formed by a procedure similar to the procedures of the display elements DE1 and DE2. Specifically, when the display element DE3 is formed, the stacked film FL3 and the sealing layer SE13 are formed in the entire display area DA and surrounding area SA. The stacked film FL3 includes, as shown in FIG. 4, the organic layer OR3 which is in contact with the lower electrode LE3 through the pixel aperture AP3, the upper electrode UE3 which covers the organic layer OR3 and the cap layer CP3 which covers the upper electrode UE3.

The organic layer OR3, the upper electrode UE3 and the cap layer CP3 are formed by vapor deposition. The sealing layer SE13 is formed by CVD. The stacked film FL3 is divided into a plurality of portions by the partition 6 having an overhang shape. The sealing layer SE13 continuously covers the portions into which the stacked film FL3 is divided, and the partition 6. By patterning these stacked film FL3 and sealing layer SE13, the display element DE3 is formed in subpixel SP3 as shown in FIG. 13I.

After the display elements DE1, DE2 and DE3 are formed, the resin layer RS1, sealing layer SE2 and resin layer RS2 shown in FIG. 4 are formed in order. In this way, the display device DSP comprising the structure shown in FIG. 4 is completed.

In the embodiment described above, the second area A2 having translucency is formed in the display area DA. By this configuration, even when a photoreceiver such as the camera CR is provided on the back surface side of the second area A2 as shown in FIG. 1, light which enters the display area DA can be detected by the photoreceiver.

The stacked films FL1, FL2 and FL3 formed by vapor deposition may have poor adherence to the base. Therefore, the stacked films FL1, FL2 and FL3 and the sealing layers SE11, SE12 and SE13 which cover these stacked films may be removed from the base when the display device DSP is manufactured. In this case, there is a possibility that the removed stacked films FL1, FL2 and FL3 and sealing layers SE11, SE12 and SE13 are attached to the substrate or contaminate the chamber of the manufacturing device.

This removal easily occurs in a case where the stacked films FL1, FL2 and FL3 are continuously formed in a wide range. In pixels PX, the stacked films FL1, FL2 and FL3 are divided into pieces by the partition 6 which surrounds subpixels SP1, SP2 and SP3. Thus, the removal described above is prevented.

Further, in the embodiment, each transmissive area TA is divided into a plurality of sub-areas AS (AS1, AS2 and AS3) by the partition 6. By this configuration, in each transmissive area TA, in a manner similar to that of each pixel PX, the stacked films FL1, FL2 and FL3 are divided into pieces, and the removal described above is prevented.

The yield of the display device DSP can be improved by preventing the removal of the stacked films FL1, FL2 and FL3 and the sealing layers SE11, SE12 and SE13 at the time of manufacturing in the above manner.

### Second Embodiment

A second embodiment discloses another configuration which may be applied to a second area A2. With regard to configurations which are not particularly referred to in this embodiment, configurations similar to those of the first embodiment can be applied.

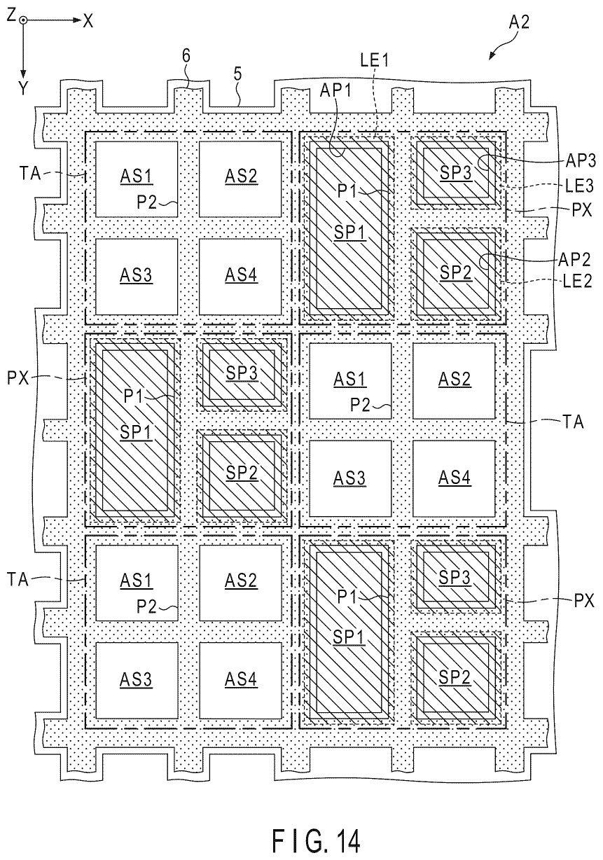

FIG. 14 is a schematic plan view showing part of the second area according to the second embodiment. In this figure, in a manner similar to that of FIG. 6, a rib layer 5, a partition 6 and lower electrodes LE1, LE2 and LE3 are shown, and the other elements are omitted. A dot pattern is added to the partition 6. A diagonal pattern is added to the lower electrodes LE1, LE2 and LE3.

In this embodiment, the number of subpixels SP included in each pixel PX is different from that of sub-areas AS included in each transmissive area TA. Specifically, in the example of FIG. 14, each pixel PX has three subpixels SP (SP1, SP2 and SP3), and each transmissive area TA has four sub-areas AS (AS1, AS2, AS3 and AS4). Thus, in the example of FIG. 14, the number of sub-areas AS included in each transmissive area TA is greater than that of subpixels SP included in each pixel PX.

In the example of FIG. 14, the sub-areas AS1 and AS2 are arranged in an X-direction, and the sub-areas AS3 and AS4 are arranged in the X-direction. The sub-areas AS1 and AS3 are arranged in a Y-direction, and the sub-areas AS2 and AS4 are arranged in the Y-direction. Further, the sub-areas AS1, AS2, AS3 and AS4 have the same shape.

The partition 6 has a first part P1 which defines subpixels SP1, SP2 and SP3 in each pixel PX, and a second part P2 which defines the sub-areas AS1, AS2, AS3 and AS4 in each transmissive area TA. In the example of FIG. 14, the shapes of these first part P1 and second part P2 are different from each other.

Specifically, in a manner similar to that of the example of FIG. 6, the first part P1 has a portion extending in the Y-direction between subpixel SP1 and subpixels SP2 and SP3, and a portion extending in the X-direction between subpixel SP2 and subpixel SP3. The second part P2 has a cruciform shape. Specifically, the second part P2 has a portion extending in the Y-direction between the sub-areas AS1 and AS3 and the sub-areas AS2 and AS4, and a portion extending in the X-direction between the sub-areas AS1 and AS2 and the sub-areas AS3 and AS4.

For example, configurations similar to those of the sub-area AS1 shown in FIG. 8, FIG. 9 and FIG. 12 can be applied to the sub-areas AS1, AS2, AS3 and AS4. In a case where an aperture 50 is provided in the rib layer 5 in the sub-areas AS1, AS2, AS3 and AS4, the linear apertures 50x and 50y shown in FIG. 10 and the dot apertures 50d shown in FIG. 11 can be applied to the aperture 50.

Even if the number of subpixels SP included in each pixel PX is different from that of sub-areas AS included in each transmissive area TA like this embodiment, effects similar to those of the first embodiment can be obtained. Further, in the example of FIG. 14, each transmissive area TA is divided into more pieces by the second part P2 of the partition 6 than the first embodiment. By this configuration, when the display device DSP is manufactured, the stacked films FL1, FL2 and FL3 formed in each transmissive area TA are divided into pieces. Thus, the removal described above is further satisfactorily prevented.

### Third Embodiment

A third embodiment discloses yet another configuration which may be applied to a second area A2. With regard to configurations which are not particularly referred to in this embodiment, configurations similar to those of the first and second embodiments can be applied.

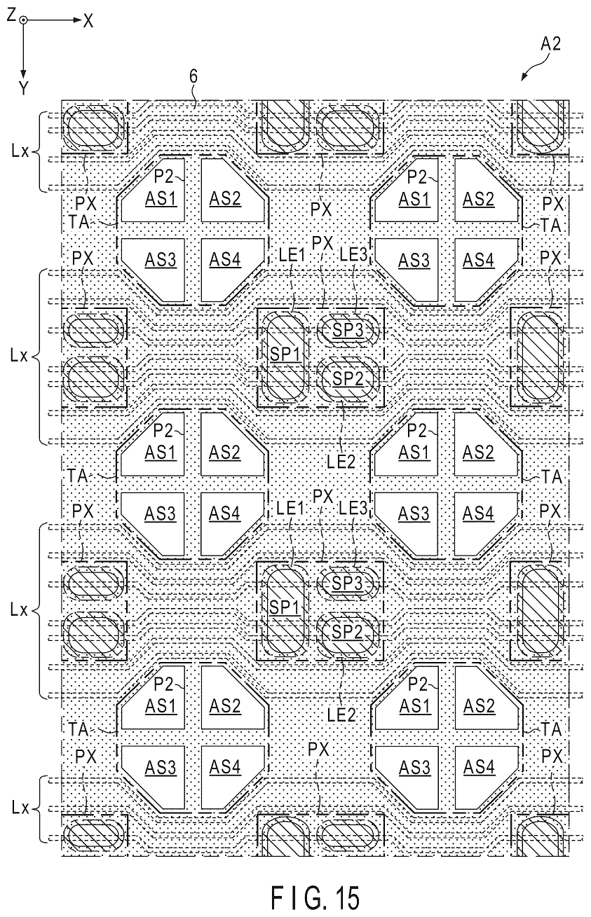

FIG. 15 is a schematic plan view showing part of the second area A2 according to the third embodiment. In this figure, a partition 6, lower electrodes LE1, LE2 and LE3 and a plurality of lines Lx extending in an X-direction are shown, and the other elements are omitted. A dot pattern is added to the partition 6. A diagonal pattern is added to the lower electrodes LE1, LE2 and LE3.

The configuration of the first area A1 of this embodiment is similar to that shown in, for example, FIG. 5. The scales of FIG. 5 and FIG. 15 are equal to each other. In other words, as is clear from comparison between the figures, in this embodiment, the size of each pixel (first pixel) PX provided in the second area A2 is different from that of each pixel (second pixel) PX provided in the first area A1. Specifically, each pixel PX provided in the second area A2 is smaller than each pixel PX provided in the first area A1.

For example, the density of pixels PX in the second area A2 is equal to that of pixels PX in the first area A1. Here, the density of pixels PX indicates the number of pixels PX which are included per unit area.

In the example of FIG. 15, each pixel PX provided in the second area A2 has subpixels SP1, SP2 and SP3 in a manner similar to that of each pixel PX provided in the first area A1. However, each of subpixels SP1, SP2 and SP3 of the second area A2 has a shape in which each corner portion is rounded.

Each transmissive area TA has four sub-areas AS1, AS2, AS3 and AS4. In the example of FIG. 15, each of these sub-areas AS1, AS2, AS3 and AS4 is a pentagon. The second part P2 of the partition 6 has a cruciform shape which defines these sub-areas AS1, AS2, AS3 and AS4. It should be noted that the shape of the sub-area AS1, AS2, AS3 or AS4 is not limited to this example, and various other shapes can be applied.

For example, configurations similar to those of the sub-area AS1 shown in FIG. 8, FIG. 9 and FIG. 12 can be applied to the sub-areas AS1, AS2, AS3 and AS4. In a case where an aperture 50 is provided in a rib layer 5 in the sub-areas AS1, AS2, AS3 and AS4, the linear apertures 50x and 50y shown in FIG. 10 and the dot apertures 50d shown in FIG. 11 can be applied to the aperture 50.

In the example of FIG. 15, no transmissive area TA is provided between pixels PX which are adjacent to each other in the X-direction or between pixels PX which are adjacent to each other in a Y-direction. Each transmissive area TA is located between pixels PX which are adjacent to each other in an oblique direction intersecting with the X-direction and the Y-direction. From another viewpoint, each transmissive area TA is provided at a position which deviates in the X-direction and the Y-direction relative to the pixels PX provided around the transmissive area TA.

In the example of FIG. 15, the area of each of the sub-areas AS1, AS2, AS3 and AS4 is greater than that of any of subpixels SP1, SP2 and SP3. The configuration is not limited to this example. The area of at least one of the sub-areas AS1, AS2, AS3 and AS4 may be less than that of one of subpixels SP1, SP2 and SP3.

Each line Lx is provided so as not to overlap the sub-area AS1, AS2, AS3 or AS4. In other words, each line Lx overlaps the partition 6 as a whole. In the example of FIG. 15, the interval between the lines Lx is narrowed between two transmissive areas TA which are arranged in the Y-direction, and is expanded between two pixels PX which are arranged in the Y-direction.

Although omitted in FIG. 15, shapes similar to those of the lines Lx can be applied to lines Ly (see FIG. 7) extending in the Y-direction. Specifically, the lines Ly may be provided so as not to overlap the transmissive areas TA. In this case, the interval between the lines Ly may be narrowed between two transmissive areas TA which are arranged in the X-direction, and expanded between two pixels PX which are arranged in the X-direction.

The display quality of the second area A2 can be improved by reducing the size of each pixel PX in the second area A2, thereby providing the pixels PX in the second area A2 at the same density as the first area A1 like this embodiment. The translucency of each transmissive area TA can be further increased by providing the lines Lx and Ly formed of a metal material and having light-shielding properties so as not to overlap the sub-area AS1, AS2, AS3 or AS4.

The first to third embodiments described above exemplarily show a case where each transmissive area TA has three or four sub-areas AS. The configuration is not limited to these examples. Each transmissive area TA may have five or more sub-areas AS, or two sub-areas AS or one sub-area AS. Further, the sub-areas AS of each transmissive area TA may have different shapes.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a first pixel provided in a display area which displays an image;
a transmissive area provided in the display area; and
a partition which includes a conductive lower portion and an upper portion having an end portion protruding from a side surface of the lower portion, and is provided in the display area, wherein
the first pixel includes a plurality of subpixels surrounded by the partition, and
the transmissive area includes a plurality of sub-areas which are surrounded by the partition and transmit at least part of light which enters the transmissive area.

2. The display device of claim 1, wherein
each of the subpixels includes:
a lower electrode;
an organic layer which covers the lower electrode and emits light based on application of voltage; and
an upper electrode which covers the organic layer and is in contact with the lower portion of the partition, and
the lower electrode is not provided in the sub-areas.

3. The display device of claim 2, wherein
neither the organic layer nor the upper electrode is provided in the sub-areas.

4. The display device of claim 3, wherein
each of the subpixels further comprises an optical adjustment layer which covers the upper electrode, and
the optical adjustment layer is not provided in the sub-areas.

5. The display device of claim 4, wherein
each of the subpixels further comprises a first sealing layer formed of an inorganic insulating material which covers the optical adjustment layer, and
the first sealing layer is not provided in the sub-areas.

6. The display device of claim 1, further comprising a rib layer which is located under the partition and is formed of an inorganic insulating material having a pixel aperture in each of the subpixels, wherein
the sub-areas overlap the rib layer.

7. The display device of claim 6, wherein
the rib layer has an aperture which overlaps at least one of the sub-areas.

8. The display device of claim 7, wherein
the aperture includes a plurality of linear apertures arranged in the sub-area.

9. The display device of claim 7, wherein
the aperture includes a plurality of dot apertures dispersed in the sub-area.

10. The display device of claim 6, further comprising a first resin layer which covers the display area, wherein
the first resin layer is in contact with the rib layer in the sub-areas.

11. The display device of claim 10, further comprising a second sealing layer formed of an inorganic insulating material which covers the first resin layer.

12. The display device of claim 11, further comprising a second resin layer which covers the second sealing layer.

13. The display device of claim 1, wherein
a number of subpixels is equal to a number of sub-areas.

14. The display device of claim 13, wherein
the subpixels include a first subpixel, a second subpixel and a third subpixel, and
the sub-areas include first, second and third sub-areas which are provided in a same positional relationship as a positional relationship of the first, second and third subpixels.

15. The display device of claim 14, wherein
the partition includes:
a first part which defines the first subpixel, the second subpixel and the third subpixel; and
a second part which defines the first sub-area, the second sub-area and the third sub-area.

16. The display device of claim 15, wherein
the first part and the second part have a same shape.

17. The display device of claim 1, wherein
a number of subpixels is different from a number of sub-areas.

18. The display device of claim 17, wherein
the number of sub-areas is greater than the number of subpixels.

19. The display device of claim 1, further comprising:
a plurality of pixel circuits which are provided in the display area and drive the subpixels, respectively; and
a plurality of lines which supply voltage or a signal to the pixel circuits, wherein
at least one of the lines overlaps the partition and does not overlap the sub-areas.

20. The display device of claim 19, wherein
the display area has a first area including a second pixel, and a second area including the first pixel and the transmissive area, and
the first pixel is smaller than the second pixel.
